(19) United States
(12) Patent Application Publication
(10) Pub. No.: US 2012/0268150 A1
(43) Pub. Date: Oct. 25, 2012

(54) CAPACITOR TEST FIXTURE AND TEST SYSTEM EMPLOYING THE SAME

(75) Inventors: QI-YAN LUO, Shenzhen City (CN); GUANG-HUA GU, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/172,303

(22) Filed: Jun. 29, 2011

(30) Foreign Application Priority Data
Apr. 22, 2011 (CN) 201110101744.9

(51) Int. Cl. G01R 31/00

(52) U.S. Cl. 324/750.16; 324/756.02

(57) ABSTRACT

A capacitor test fixture for positioning capacitors under test includes a main body, a clamping section, an operating section, and a cover. The main body defines an opening, a plurality of receiving slots at the bottom of the opening to receive the capacitors, some positioning slots located at opposite sides of the opening, and a sliding slot. The clamping section includes a first hook, and the operating section includes a second hook corresponding to the first hook. The cover locates and fixes the clamping section and the operating section to the main body. The operating section functions when the second hook holds back the first hook, the capacitors under test are received within the receiving slots, and when the second hook releases the first hook, the clamping section secures and makes contact with the capacitors for testing.

### BACKGROUND

1. Technical Field

The disclosure generally relates to mechanical devices, and more particularly to a capacitor test fixture and a test system employing the same.

2. Description of the Related Art

The capacitance of capacitors on a circuit board often needs to be tested to ensure that dependent circuits on the circuit board are working normally. However, the capacitance of capacitors mounted on the circuit board cannot be directly measured easily due to their small size. For example, some capacitors, such as chip capacitors, cannot be accessed by probes reliably because of the small package in which they are presented, which may result in test errors and inaccurate results.

Therefore, there is room for improvement within the art.

### BRIEF DESCRIPTION OF THE DRAWINGS

Many aspects of a capacitor test fixture and test system employing the same can be better understood with reference to the following drawings. The components in the drawings are not necessarily drawn to scale, the emphasis instead being placed upon clearly illustrating the principles of the capacitor test fixture and test system employing the same. Moreover, in the drawings, like reference numerals designate corresponding parts throughout the several views. Wherever possible, the same reference numbers are used throughout the drawings to refer to the same or like elements of an embodiment.

FIG. 1 is a schematic and exploded view of a capacitor test fixture used in a test system, according to one embodiment of the disclosure.

FIG. 2 is a schematic and assembled view of the capacitor test fixture shown in FIG. 1 of the disclosure.

FIG. 3 is an assembled cross-sectional view of the capacitor test fixture when securing and testing capacitors under test shown in FIG. 2 of the disclosure.

FIG. 4 is an assembled cross-sectional view of the capacitor test fixture when excluding the capacitors under test shown in FIG. 3 of the disclosure.

FIG. 5 is a circuit view of a test circuit of the test system of the disclosure.

### DETAILED DESCRIPTION

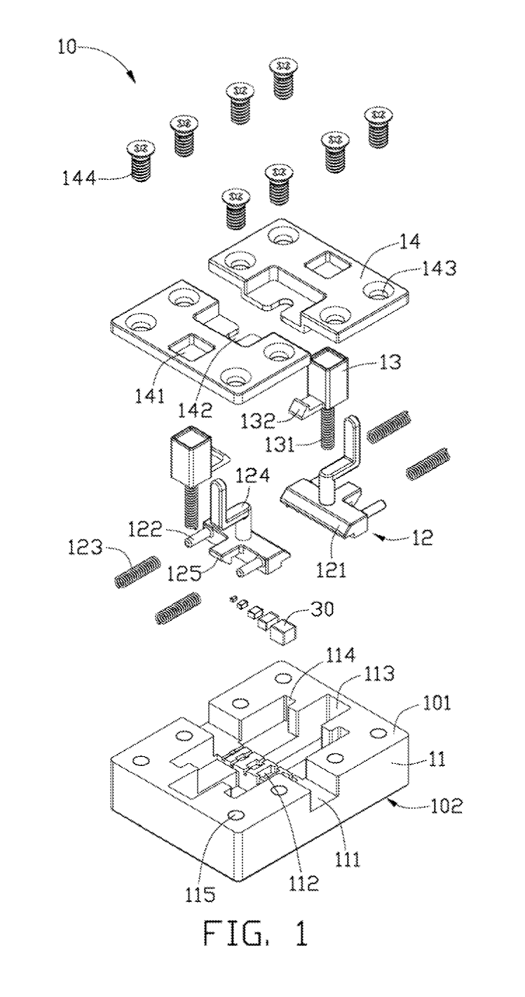

FIG. 1 shows an exploded view of a capacitor test fixture 10 used in a test system (not shown), according to one embodiment of the disclosure. The test system is capable of measuring and obtaining the capacitance of different capacitors 30, and is positioned in a housing (not shown). The capacitor test fixture 10 is received and is secured within the housing.

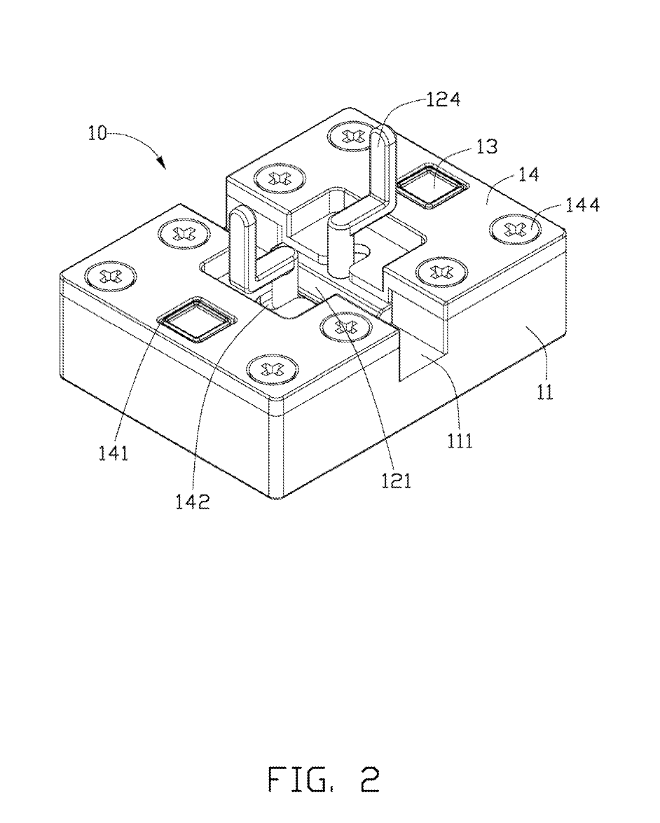

Referring to FIG. 2, the capacitor test fixture 10 includes a main body 11, two clamping sections 12, two operating sections 13, and two covers 14. In this embodiment, the main body 11 is substantially a cuboid, and includes an operating surface 101 and a bottom surface 102 correspondingly parallel to the operating surface 101. The operating surface 101 defines a large and substantially rectangular slot or opening (opening 111) at opposite sides of, and extending through, the main body 11.

The opening 111 defines a plurality of receiving slots 112 at the bottom surface of the opening 111, and each receiving slot 112 has a different shape and size. In this embodiment, the shapes and sizes of the receiving slots 112 substantially match and correspond to those of the capacitors 30 under test. The receiving slots 112 are configured for receiving the capacitors 30 under test.

The operating surface 101 further defines two positioning slots 113 and four sliding slots 114. In this embodiment, the two positioning slots 113 are substantially rectangular and are symmetrically arranged about the opening 111. The positioning slots 113 communicate with the opening 111 and are capable of receiving corresponding operating sections 13. The four sliding slots 114 are substantially rectangular and each pair (of the two pairs of the sliding slots 114) flanks a positioning slot 113 of the two positioning slots 113. In this embodiment, the opening 111 divides the operating surface 101 into two substantially similar parts, each part includes one positioning slot 113 and two sliding slots 114, and the positioning slot 113 is parallel to the two sliding slots 114. The main body 11 further defines a plurality of through mounting holes (mounting holes 115) adjacent to the edge of the operating surface 101.

The clamping sections 12 are substantially rectangular blocks, and each clamping section 12 includes a holding portion 121 which slopes downwards towards the opposing clamping section. The two holding portions 121 face each other, and the capacitors 30 under test are held immovably in place between the two holding portions 121. Each clamping section 12 further includes two guiding posts 122 and two elastic portions 123. The guiding posts 122 are effectively located behind the holding portions 121, and function in support of them. The uncompressed length of the elastic portion 123 is greater than that of the corresponding post 122. One end of the elastic portion 123 is removably assembled onto the corresponding guiding post 122, and the other end is fixed on the sidewall of the corresponding sliding slot 114. In this embodiment, each elastic portion 123 is a cylindrical spring.

Each clamping section 12 further includes a handle 124 and a first hook 125. The handle 124 is located on the upper surface of the clamping section 12, and the first hook 125 is positioned between the guiding posts 122. The two clamping sections 12 move back and forth along the corresponding sliding slots 114 by operating and moving the handles 124, as to hold or release the capacitors 30 under test in the receiving slots 112.

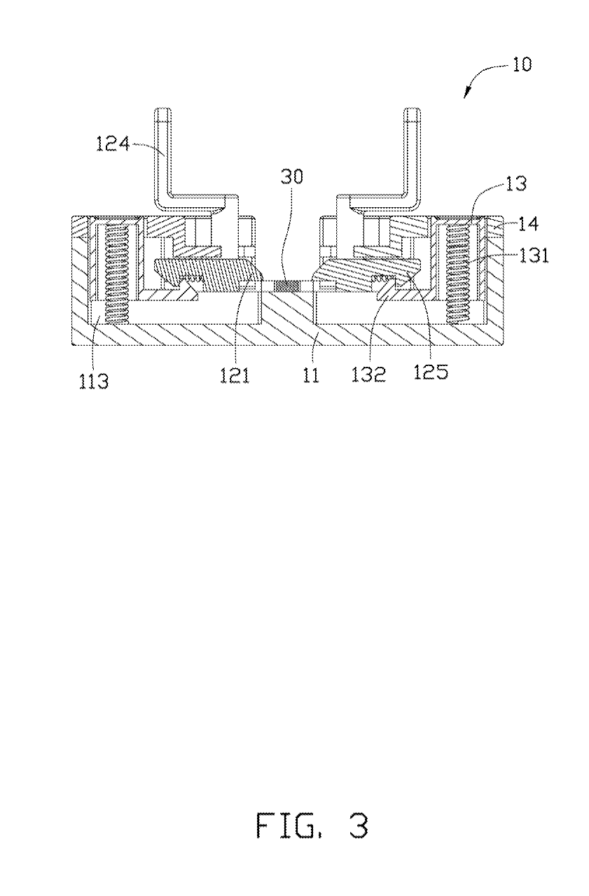

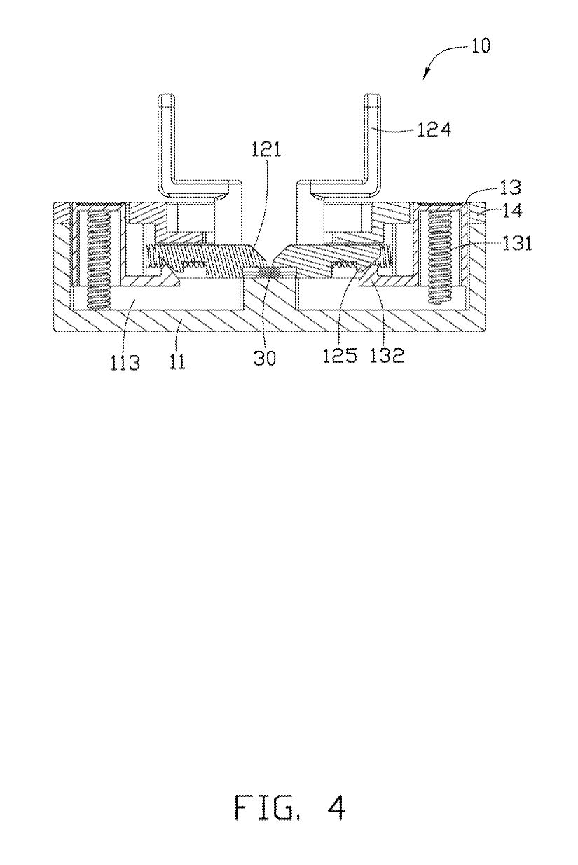

Further referring to FIGS. 3 and 4, the buttons (operating sections 13) are substantially square in section and are removably received within the corresponding positioning slots 113. Each operating section 13 includes a spring 131 and an integral second hook 132. One end of the spring 131 is fixed in the operating section 13, and the other end rests on the bottom of the positioning slot 113, thereby, the operating sections 13 can move up and down in the positioning slots 113. The second hooks 132 interact with the first hooks 125 to lock back the first hooks 125 and release them.

In this embodiment, when the two handles 124 are moved away from each other in opposite directions, the clamping sections 12 slide along the sliding slots 114, the first hooks 125 hold and fasten the corresponding second hooks 132. Thus, the two clamping sections 12 are held back by the second hooks 132, and the elastic portions 123 are compressed. The receiving slots 112 are thus exposed to hold and receive the capacitors 30 under test. When the capacitors 30 are received within the receiving slots 112, the operating sections 13 can be pushed down into the positioning slots 113 to further compress the springs 131, the first hooks 125 unfasten and separate the lock from the second hooks 132. Thus, the clamping sections 12 move closer to each other under the action of the elastic force of the elastic portions 123, until the holding portions 121 make contact with and secure the capacitors 30 under test.

The covers 14 are flat for the main part and are mounted on the main body 11. Each cover 14 defines a through hole 141 and a gap 142. The through hole 141 aligns with the corresponding operating section 13, so the operating section 13 is exposed and passes through the corresponding through hole 141. In this embodiment, the gaps 142 are substantially rectangular and are aligned with the corresponding handles 124. Thus, the handles 124 are configured for moving a short distance along the corresponding gaps 142.

The cover 14 further defines a plurality of screw holes 143 extending through the cover 14, the screw holes 143 are aligned with the corresponding mounting holes 115 on the main body 11. The screw holes 143 are configured for receiving the corresponding screws 144, so that the covers 14 are fixed to the main body 11 through the screws 144.

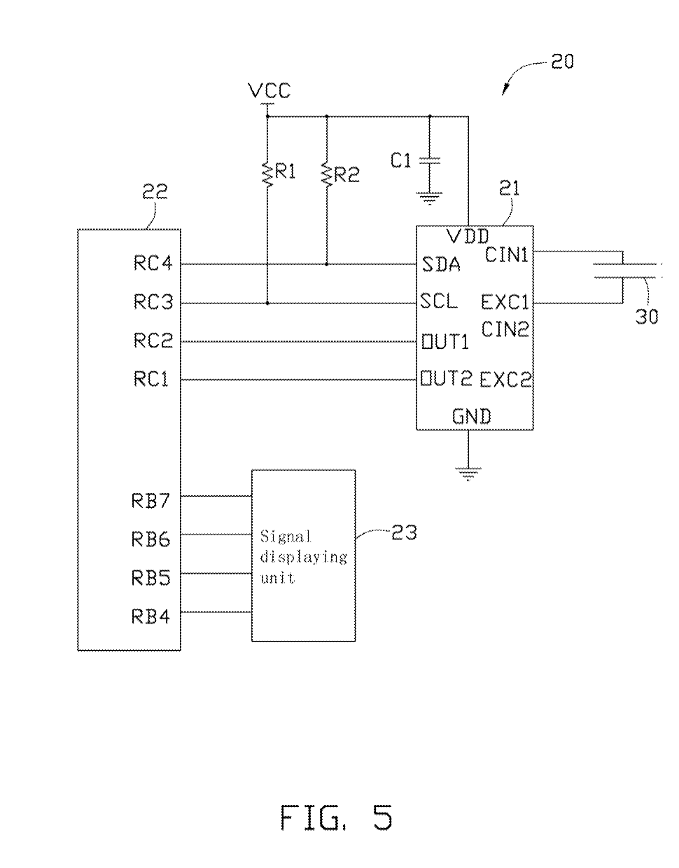

Also referring to FIG. 5, the test circuit 20 includes a test unit 21, a signal processing unit 22, a signal displaying unit 23, a capacitor C1, and two resistors R1 and R2. The test unit 21 can be an AD7150 integrated circuit and includes a power pin VDD, a ground pin GND, a first group of test pins CIN1 and EXC1, a second group of test pins CIN2 and EXC2, a clock pin SCL, a data pin SDA, and two output pins OUT1 and OUT2.

In this embodiment, the power pin VDD is electrically connected to a power source VCC and is electrically connected to ground through the capacitor C1. The ground pin GND is electrically connected to ground. The capacitor 30 under test is electrically connected between the test pins CIN1 and EXC1 or the test pins CIN2 and EXC2 to test and obtain the capacitance of the capacitors 30 under test.

The signal processing unit 22 can be a PIC1674 microcontroller and includes a group of data transmission pins RC1-RC4 and a group of data output pins RB4-RB7. In this embodiment, the data transmission pins RC1-RC4 are electrically connected to the output pins OUT2 and OUT1, the clock pin SCL and the data pin SDA, respectively. The data transmission pins RC3 and RC4 are electrically connected to the power source VCC through the resistors R1 and R2 respectively. The data output pins RB4-RB7 are electrically connected to the signal displaying unit 23. The signal processing unit 22 is capable of processing test data from the test unit 21 to generate test results and outputting the test results to the signal displaying unit 23 through the data output pins RB4-RB7. The signal displaying unit 23 can be a MZLH04-12864 microchip to display the test results, such as capacitance of the capacitors 30 under test.

Referring to FIGS. 1-4, in assembly, the operating sections 13 are received in the corresponding positioning slots 113, and the clamping sections 12 are received within the corresponding positioning slots 113 and the sliding slots 114. In detail, the holding portions 121 face toward each other, the first hooks 125 face toward the second hooks 132, one end of the elastic portion 123 is assembled to the guiding post 122, and the other end is fixed on the sidewall of the sliding slot 114. The through holes 141 are aligned with the corresponding operating sections 13, the handles 124 are aligned with and slide within the corresponding gaps 142. The screw holes 143 are aligned with the mounting holes 115 on the main body 11, and the screws 144 extend through the screw holes 143 and the mounting holes 155 to fix and assemble covers 14 to the main body 11.

To test the capacitors 30 under test, the two handles 134 are moved away from each other in opposite direction, the guiding posts 122 of the clamping sections 12 slide along the sliding slots 114, and the first hooks 125 hold and fasten the corresponding second hooks 132. Thus, the two clamping sections 12 are fixed, and the elastic portions 123 are compressed. The receiving slots 112 are exposed, and the capacitors 30 under test are received within corresponding receiving slots 112 according to their types and sizes. By pressing the operating sections 13 along the positioning slots 113, the clamping sections 12 move close to each other under the action of the elastic force of the elastic portions 123, and the holding portions 121 secure and contact the capacitors 30 under test, preventing the capacitors 30 movement. The test circuit 20 is powered on to measure the capacitance of the capacitors 30 under test, and the test results are displayed on the signal displaying unit 23.

In summary, the capacitor test fixture 10 can effectively fix the capacitors 30 under test and prevent the capacitors 30 movement by operating the handles 124 and the operating sections 13. Moreover, the capacitor test fixture 10 has a simple structure and is easy for operation, which can quickly and efficiently test the capacitors 30 under test, even if the small chip capacitors.

In the present specification and claims the word “a” or “an” preceding an element does not exclude the presence of a plurality of such elements. Further, the word “comprising” does not exclude the presence of other elements or steps than those listed.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A capacitor test fixture for positioning capacitors under test, comprising:
a main body defining an opening, a plurality of receiving slots at the bottom of the opening to receive the capacitors under test, a positioning slot located at one side of the opening, and a sliding slot located adjacent to the positioning slot;
a clamping section removably located at the positioning slots and the sliding slots, the clamping section comprising a first hook;
an operating section removably located at the positioning slot, and the operating section comprising a second hook corresponding to the first hook; and
a cover for assembling the clamping section and the operating section to the main body, wherein the operating section is operated, when the second hook fastens the first hook, the capacitors under test can be received within the receiving slots, when the second hook is detached from the first hook, the clamping section secures and contacts the capacitors to test the capacitors.

2. The capacitor test fixture as claimed in claim 1, wherein the main body comprises an operating surface, the opening is located at the operating surface and extends sideward to the opposite sides of the main body, and the main body defines two positioning slots and four sliding slots, the capacitor test fixture further comprises another operating section and another clamping section.

3. The capacitor test fixture as claimed in claim 2, wherein the two positioning slots are symmetrically arranged about the opening, the positioning slots communicate with the opening and are capable of receiving corresponding operating sections, each pair of the two pairs of the sliding slots flanks a positioning slot of the two positioning slots, and the positioning slot is located parallel between two corresponding sliding slots.

4. The capacitor test fixture as claimed in claim 2, wherein each clamping section comprises a holding portion, the two holding portions face to each other, and the capacitors under test are held immovably in place between the two hold portions to prevent the capacitors movement.

5. The capacitor test fixture as claimed in claim 4, wherein the clamping section further comprises two guiding posts and two elastic portions, the guiding posts are located behind the holding portions and function in support of them, the length of the elastic portion is greater than that of the corresponding post, one end of the elastic portion is removably assembled onto the corresponding guiding post, and the other end is fixed on the sidewall of the corresponding sliding slot.

6. The capacitor test fixture as claimed in claim 5, wherein the clamping section further comprises a handle, the handle is located on the upper surface of the clamping section, the two clamping sections relatively move back and forth along the sliding slots by operating and moving the handles to hold or release the capacitors under test in the receiving slots.

7. The capacitor test fixture as claimed in claim 6, wherein each operating section comprises a spring, one end of the spring is fixed in the operating section, the other end rests on the bottom of the positioning slot, and the operating sections move up and down in the positioning slots.

8. The capacitor test fixture as claimed in claim 7, wherein when the two handles are moved away from each other in opposite direction, the clamping sections slide along the sliding slots, the first hooks interact with the first hooks to lock back and release the first hooks, the two clamping sections are held back by the second hooks, the elastic portions are compressed, the receiving slots are exposed to hold and receive the capacitors under test.

9. The capacitor test fixture as claimed in claim 8, wherein when the capacitors are received within the receiving slots, the operating sections can be pushed down into the positioning slots to further compress the springs, the first hooks unfasten and separate the lock from the second hooks, the clamping sections move close to each other according to the elastic force of the elastic portions, and the holding portions make contact with and secure the capacitors under test.

10. The capacitor test fixture as claimed in claim 6, wherein each cover defines a gap, a through hole and a plurality of screw holes, the operating section is aligned with and passes through the corresponding through hole, the handles are aligned with and move along the corresponding gaps, the screw holes are configured for receiving corresponding screws to fix and assemble covers to the main body.

11. A test system for testing capacitance of capacitors under test, comprising:
a capacitor test fixture for fixing the capacitors under test and comprising:
a main body defining a receiving space;
a clamping section received within the receiving space, and the clamping section comprising a first hook;
a operating section received within the receiving space, and the operating section comprising a second hook corresponding to the first hook; and
a cover for covering the clamping section and the operating section into the main body; and
a test circuit for being electrically connected to the capacitors under test, wherein when the second hook fasten the first hook, the capacitors are received within the corresponding receiving space, when the operating section is pressed, the first hook is released from the second hook, the clamping section makes contact with and secures the capacitors under test, and the test circuit measures the capacitance of the capacitors under test.

12. The test system as claimed in claim 11, wherein the receiving space comprising an opening, a plurality of receiving slots, two positioning slots, and four sliding slots, the receiving slots is located at the bottom of the opening to receive the capacitors under test, the positioning slots are averagely arranged at opposite sides of the opening, the four sliding slots are averagely located at opposite side of the opening, and the capacitor test fixture further comprises another operating section and another clamping section.

13. The test system as claimed in claim 12, wherein the two positioning slots are symmetrically arranged about the opening, the positioning slots communicate with the opening and are capable of receiving corresponding operating sections, each pair of the two pairs of the sliding slots flanks a positioning slot of the two positioning slots, and the positioning slot is located parallel between two corresponding sliding slots.

14. The test system as claimed in claim 12, wherein each clamping section comprises a holding portion, the two holding portions face to each other, and the capacitors under test are held immovably in place between the two hold portions to prevent the capacitors movement.

15. The test system as claimed in claim 14, wherein the clamping section further comprises two guiding posts and two elastic portions, the guiding posts are located behind the holding portions and function in support of them, the length of the elastic portion is greater than that of the corresponding post, one end of the elastic portion is removably assembled onto the corresponding guiding post, and the other end is fixed on the sidewall of the corresponding sliding slot.

16. The test system as claimed in claim 15, wherein the clamping section further comprises a handle, the handle is located on the upper surface of the clamping section, the two clamping sections relatively move back and forth along the sliding slots by operating and moving the handles to hold or detach the capacitors under test in the receiving slots.

17. The test system as claimed in claim 16, wherein each operating section comprises a spring, one end of the spring is fixed in the operating section, the other end rests on the bottom of the positioning slot, and the operating sections move up and down in the positioning slots.

18. The test system as claimed in claim 17, wherein when the two handles are moved away from each other, the clamping sections slide along the sliding slots, the first hooks fasten and hold back the corresponding second hooks, the two clamping sections are held back by the second hooks, the elastic portions are compressed, the receiving slots are exposed to hold the capacitors under test; when the capacitors are received within the receiving slots, the operating sections can be pushed down into the positioning slots to further compress the springs, the first hooks separate the connection from the second hooks, the clamping sections move close to each other according to the elastic force of the elastic portions, and the holding portions make contact with and secure the capacitors under test.

19. The test system as claimed in claim 16, wherein each cover defines a gap, a through hole and a plurality of screw holes, the operating section is aligned with and passes through the corresponding through hole, the handles are aligned with and move along the corresponding gaps, the screw holes are configured for receiving corresponding screws to fix and assemble covers to the main body.

20. The test system as claimed in claim 11, wherein the test circuit comprises a test unit, a signal processing unit, and a signal displaying unit, the test unit comprises a group of test pins, the test pins of the test unit are electrically connected to the capacitors under test to obtain test data the capacitors, the signal processing unit is electrically connected to the test unit to process the test date to generate test results and output the test results to the signal displaying unit, and the signal displaying unit displays the test results of the capacitors.
